(19) United States
(12) Patent Application Publication
(10) Pub. No.: US 2023/0085063 A1
(43) Pub. Date: Mar. 16, 2023

(54) VCSEL CHIP FOR GENERATION OF LINEAR STRUCTURED LIGHT PATTERNS AND FLOOD ILLUMINATION

(71) Applicant: Facebook Technologies, LLC, Menlo Park, CA (US)

(72) Inventors: Jonatan Ginzburg, Sunnyvale, CA (US); Benjamin Nicholas Jones, Mountain View, CA (US); Arun Kumar Nallani Chakravartula, San Jose, CA (US); Jun Li, San Mateo, CA (US); Lawrence Chang-Yung Wang, Mountain View, CA (US)

(21) Appl. No.: 17/572,395

(22) Filed: Jan. 10, 2022

Related U.S. Application Data
(60) Provisional application No. 63/243,514, filed on Sep. 13, 2021.

(51) Int. Cl. H01S 5/42; G01B 11/22

(52) U.S. Cl. CPC H01S 5/423; G01B 11/22; G02B 3/06

(57) ABSTRACT

A vertical cavity surface emitting laser (VCSEL) chip includes a structured light (SL) VCSEL array, and a fill VCSEL array. The SL VCSEL array includes a plurality of first VCSELs on a substrate. The fill VCSEL array includes a plurality of second VCSELs on the substrate. The fill VCSEL array is positioned orthogonal to the SL VCSEL array on the substrate. Light emitted from the SL VCSEL array may be used to form a bar pattern, and light from the SL VCSEL array and the fill VCSEL array together may be used to form flood illumination.

### CROSS-REFERENCE TO RELATED APPLICATIONS

This application claims the benefit of U.S. Provisional Application No. 63/243,514, filed Sep. 13, 2021, which is incorporated by reference in its entirety.

### FIELD OF THE INVENTION

This disclosure relates generally to vertical cavity surface emitting laser (VCSEL) arrays, and more specifically to a VCSEL chip for generation of linear structured light patterns and flood illumination.

### BACKGROUND

Depth sensing systems determine depth information describing a local area. Conventional depth sensing systems, in particular those with small form factors (e.g., head mounted), generally are capable of projecting structured light patterns or flood illumination, but not both.

### SUMMARY

A depth camera assembly (DCA) determines depth information for a local area. The DCA includes at least one camera and at least one illuminator. The illuminator comprises a VCSEL chip. The VCSEL chip may generate one or more linear structured light (SL) patterns or flood illumination. The one or more SL patterns may be used to, e.g., illuminate a local area with a SL bar pattern, or selectively illuminate one or more portions of the local area. The flood illumination illuminates all of the local area. One or more cameras of the DCA captures images of the illuminated local area. The DCA determines depth information using the captured images and a depth sensing mode (e.g., SL or assisted stereo for a linear bar pattern or TOF for flood illumination).

In some embodiments, a VCSEL chip is described. The VCSEL chip includes a first VCSEL array, and a second VCSEL array. The first VCSEL array includes a plurality of first VCSELs on a substrate. The second VCSEL array includes a plurality of second VCSELs on the substrate. The second VCSEL array is positioned orthogonal to the first VCSEL array on the substrate. Light emitted from the first VCSEL array is used to form a bar pattern, and light emitted from the first VCSEL array and the second VCSEL array together is used to form flood illumination.

In some embodiments, a DCA is described. The DCA includes a VCSEL chip, and optical assembly, a camera, and a controller. The VCSEL chip includes a first VCSEL array and a second VCSEL array. The first VCSEL array includes a plurality of first VCSELs on a substrate. The second VCSEL array includes a plurality of second VCSELs on the substrate. The second VCSEL array is positioned orthogonal to the first VCSEL array on the substrate. The optical assembly is configured to condition light from the VCSEL chip and project the conditioned light into a local area of the DCA. The conditioned light forms one of a bar pattern or flood illumination. Light emitted from the first VCSEL array is used to form the bar pattern, and light emitted from the first VCSEL array and the second VCSEL array together is used to form the flood illumination. The camera is configured to capture images of the local area illuminated with the conditioned light. The controller is configured to instruct the VCSEL chip to emit light in order to form one of the flood illumination or the bar pattern, and determine depth information for the local area using the captured images.

In some embodiments a non-transitory computer readable medium is described. The non-transitory computer readable medium is configured to store program code instructions that when executed by a processor of a depth camera assembly (DCA), cause the DCA to perform steps. The steps include instructing a vertical cavity surface emitting laser (VCSEL) chip to emit light in order to form one of flood illumination or a bar pattern. The VCSEL chip comprises a first VCSEL array including a plurality of first VCSELs on a substrate, and a second VCSEL array including a plurality of second VCSELs on the substrate, the second VCSEL array positioned orthogonal to the first VCSEL array on the substrate. The steps also include conditioning, via an optical assembly, light from the VCSEL chip. The steps also include projecting the conditioned light into a local area of the DCA, the conditioned light forming one of the bar pattern or the flood illumination. Light emitted from the first VCSEL array is used to form the bar pattern, and light emitted from the first VCSEL array and the second VCSEL array together is used to form the flood illumination. The steps also include capturing images of the local area illuminated with the conditioned light, and determining depth information for the local area using the captured images.

### BRIEF DESCRIPTION OF THE DRAWINGS

FIG. 1A is a perspective view of a headset implemented as an eyewear device, in accordance with one or more embodiments.

FIG. 1B is a perspective view of a headset implemented as a head-mounted display, in accordance with one or more embodiments.

FIG. 2 is a block diagram of a DCA, in accordance with one or more embodiments.

FIG. 3 is a schematic diagram of a DCA in a local area, in accordance with one or more embodiments.

FIG. 4A is a plan view of a linear SL pattern, in accordance with one or more embodiments.

FIG. 4B is a plan view of flood illumination, in accordance with one or more embodiments.

FIG. 5A is a plan view of a VCSEL chip, in accordance with one or more embodiments.

FIG. 5B is a portion of the VCSEL chip of FIG. 5A.

FIG. 5C is an example current driver for the VCSEL chip of FIG. 5A.

FIG. 6 is a flowchart illustrating a process for generating a linear SL pattern or flood illumination, in accordance with one or more embodiments.

FIG. 7 is a system that includes a headset, in accordance with one or more embodiments.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

A depth camera assembly (DCA) determines depth information for a local area. The DCA may be integrated into, e.g., a headset. The DCA includes at least one illuminator that includes a VCSEL chip. The DCA may instruct the VCSEL chip to emit one or more different linear SL patterns, or flood illumination, in accordance with a specific depth sensing mode. The depth sensing mode may include, e.g., SL, time-of-flight (ToF), and assisted stereo. ToF may refer to indirect ToF or direct ToF. And assisted stereo refers to using SL to provide texture in captured images, which the DCA then processes using conventional stereo methods. If the depth sensing mode is SL or assisted stereo, the DCA instructs the VCSEL chip to emit a linear SL pattern. In contrast, if the depth sensing mode is ToF, then the DCA instructs the VCSEL chip to emit flood illumination. The camera assembly captures images of the illuminated local area. The DCA determines depth information using the captured images and a depth sensing mode (e.g., SL or assisted stereo for a linear bar pattern or TOF for flood illumination).

The VCSEL chip illuminates the local area in accordance with instructions from a controller of the DCA. The VCSEL chip includes a SL VCSEL array, and a fill VCSEL array. The SL VCSEL array includes a plurality of first VCSELs on a substrate. In some embodiments, the plurality of first VCSELs have a substantially rectangular emission array. And each of plurality of first VCSELs have a respective emission region over a first length (e.g., long dimension of rectangle). The fill VCSEL array includes a plurality of second VCSELs on the substrate. The fill VCSEL array is positioned orthogonal to the SL VCSEL array on the substrate. In some embodiments, each of the plurality of second VCSELs have a respective emission region over a second length.

The DCA is configured to condition light (e.g., via an optical assembly) from the VCSEL chip and project the conditioned light into a local area of the DCA. The DCA includes at least one cylindrical lens that functions to substantially spread the light from the VCSEL chip in one dimension. In this manner, light from the SL VCSEL array is spread to form a linear SL pattern (i.e., a bar pattern) that includes parallel bars of light that are separated by dark spaces. Note that different rows of the VCSELs in the SL VCSEL array are individually addressable. In this manner, some or all of the “bars” of the linear SL pattern may be selectively activated, enabling a set of different linear SL patterns that may be obtained based on which rows of VCSELs are active and which rows of VCSELS are inactive. The DCA may also output flood illumination. The DCA may instruct both the SL VCSEL array and the fill VCSEL array to concurrently emit light. The light from the fill VCSEL array is spread by the cylindrical lens to form a second pattern. And due to positioning of the fill VCSEL array, the generated second pattern functions to fill in the dark spaces of the linear SL pattern, thereby, forming flood illumination.

The DCA captures images (e.g., via a camera assembly) of the local area illuminated with the light from the VCSEL chip. The DCA determines depth information for the illuminated portion of the local area using the captured images and a depth sensing mode (e.g., SL, ToF, assisted stereo).

As noted above, the DCA may generate SL patterns of varying size or flood illumination using the VCSEL chip. As opposed to conventional depth sensing systems which typically are restricted to either SL illumination or flood illumination, but not both.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to create content in an artificial reality and/or are otherwise used in an artificial reality. The artificial reality system that provides the artificial reality content may be implemented on various platforms, including a wearable device (e.g., headset) connected to a host computer system, a standalone wearable device (e.g., headset), a mobile device or computing system, or any other hardware platform capable of providing artificial reality content to one or more viewers.

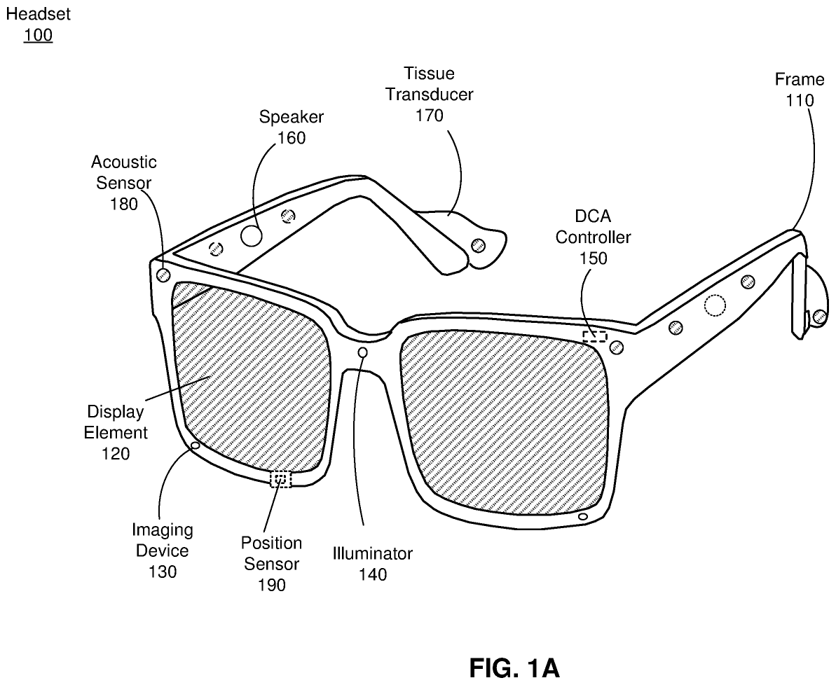

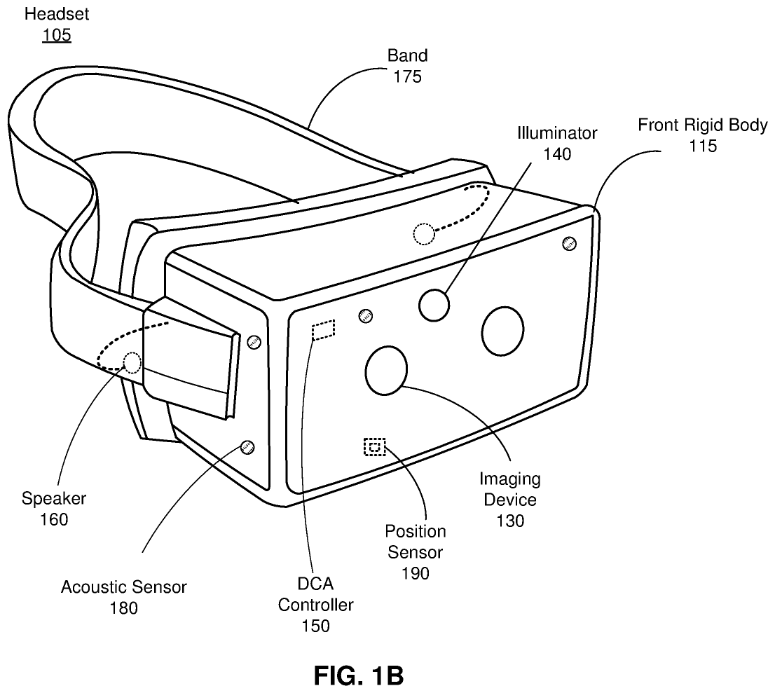

FIG. 1A is a perspective view of a headset 100 implemented as an eyewear device, in accordance with one or more embodiments. In some embodiments, the eyewear device is a near eye display (NED). In general, the headset 100 may be worn on the face of a user such that content (e.g., media content) is presented using a display assembly and/or an audio system. However, the headset 100 may also be used such that media content is presented to a user in a different manner. Examples of media content presented by the headset 100 include one or more images, video, audio, or some combination thereof. The headset 100 includes a frame, and may include, among other components, a display assembly including one or more display elements 120, a depth camera assembly (DCA), an audio system, and a position sensor 190. While FIG. 1A illustrates the components of the headset 100 in example locations on the headset 100, the components may be located elsewhere on the headset 100, on a peripheral device paired with the headset 100, or some combination thereof. Similarly, there may be more or fewer components on the headset 100 than what is shown in FIG. 1A.

The frame 110 holds the other components of the headset 100. The frame 110 includes a front part that holds the one or more display elements 120 and end pieces (e.g., temples) to attach to a head of the user. The front part of the frame 110 bridges the top of a nose of the user. The length of the end pieces may be adjustable (e.g., adjustable temple length) to fit different users. The end pieces may also include a portion that curls behind the ear of the user (e.g., temple tip, ear piece).

The one or more display elements 120 provide light to a user wearing the headset 100. As illustrated the headset includes a display element 120 for each eye of a user. In some embodiments, a display element 120 generates image light that is provided to an eyebox of the headset 100. The eyebox is a location in space that an eye of user occupies while wearing the headset 100. For example, a display element 120 may be a waveguide display. A waveguide display includes a light source (e.g., a two-dimensional source, one or more line sources, one or more point sources, etc.) and one or more waveguides. Light from the light source is in-coupled into the one or more waveguides which outputs the light in a manner such that there is pupil replication in an eyebox of the headset 100. In-coupling and/or outcoupling of light from the one or more waveguides may be done using one or more diffraction gratings. In some embodiments, the waveguide display includes a scanning element (e.g., waveguide, mirror, etc.) that scans light from the light source as it is in-coupled into the one or more waveguides. Note that in some embodiments, one or both of the display elements 120 are opaque and do not transmit light from a local area around the headset 100. The local area is the area surrounding the headset 100. For example, the local area may be a room that a user wearing the headset 100 is inside, or the user wearing the headset 100 may be outside and the local area is an outside area. In this context, the headset 100 generates VR content. Alternatively, in some embodiments, one or both of the display elements 120 are at least partially transparent, such that light from the local area may be combined with light from the one or more display elements to produce AR and/or MR content.

In some embodiments, a display element 120 does not generate image light, and instead is a lens that transmits light from the local area to the eyebox. For example, one or both of the display elements 120 may be a lens without correction (non-prescription) or a prescription lens (e.g., single vision, bifocal and trifocal, or progressive) to help correct for defects in a user's eyesight. In some embodiments, the display element 120 may be polarized and/or tinted to protect the user's eyes from the sun.

In some embodiments, the display element 120 may include an additional optics block (not shown). The optics block may include one or more optical elements (e.g., lens, Fresnel lens, etc.) that direct light from the display element 120 to the eyebox. The optics block may, e.g., correct for aberrations in some or all of the image content, magnify some or all of the image, or some combination thereof.

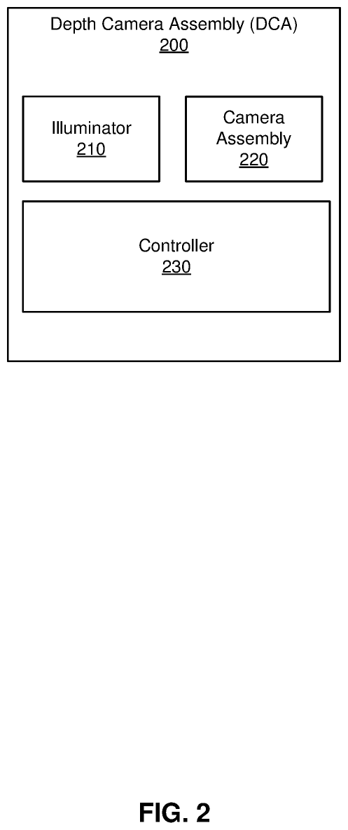

The DCA determines depth information for a portion of a local area surrounding the headset 100. The DCA includes a camera assembly, a DCA controller 150, and an illuminator 140. The DCA instructs the illuminator 140 to illuminate at least a portion of the local area with light in accordance with a particular depth sensing mode. The depth sensing mode may be, e.g., SL, TOF, or assisted stereo. In some embodiments, if the depth sensing mode is SL or assisted stereo, the DCA controller 150 instructs the illuminator 140 to emit a linear SL pattern, and if the depth sensing mode is ToF, then the DCA controller 150 instructs the illuminator 140 to emit flood illumination. Note in some embodiments, the DCA controller 150 may also use TOF to process an image of a local area illuminated with a linear SL pattern. The DCA is discussed in detail below with regard to, e.g., FIGS. 2-7.

For example, the DCA may instruct the VCSEL chip to emit one or more different linear SL patterns, or flood illumination, in accordance with a specific depth sensing mode. The light may be, e.g., a linear SL pattern (e.g., parallel lines) or flood illumination in the infrared (IR). In some embodiments, the one or more imaging devices 130 capture images of the portion of the local area that include the light from the illuminator 140. As illustrated, FIG. 1A shows a single illuminator 140 and two imaging devices 130.

The illuminator 140 projects a linear SL pattern, of a set of possible linear SL patterns, or flood illumination into a local area or portions thereof. The illuminator 140 comprises a VCSEL chip and an optical assembly. The VCSEL chip includes a SL VCSEL array, and a fill VCSEL array. The SL VCSEL array includes a plurality of first VCSELs on a substrate. And each of plurality of first VCSELs have a respective emission region over at least a first length. In some embodiments, the VCSEL chip may include additional VCSEL arrays parallel to the SL VCSEL array that have respective emission regions greater than the first length. Moreover, in some embodiments, a particular VCSEL array may include emission regions of differing lengths. For example, rows of VCSELS with longer emission areas in one VCSEL array may be used for determined depth in the far field, and rows of VCSELS with shorter emission areas in the SL VCSEL array may be used for determining depth in the near field. The fill VCSEL array includes a plurality of second VCSELs on the substrate. The fill VCSEL array is positioned orthogonal to the SL VCSEL array on the substrate. Light emitted from the SL VCSEL array is used to form a bar pattern, and light emitted from the SL VCSEL array and the fill VCSEL array together is used to form flood illumination.

The optical assembly is configured to condition light from the VCSEL chip and project the conditioned light into the local area. The optical assembly includes at least one cylindrical lens that functions to substantially spread the light from the VCSEL chip in one dimension. In this manner, light from the SL VCSEL array is spread to form a first linear SL pattern (i.e., a bar pattern) that includes parallel bars of light that are separated by dim regions. A dim region is the dark space between adjacent bars of light. In some embodiments, different rows of VCSELs in the SL VCSEL array are individually addressable. In this manner, some or all of the “bars” of the linear SL pattern may be selectively activated, enabling a set of different linear SL patterns that may be obtained based on which rows of VCSELs are active and which rows of VCSELS are inactive.

The illuminator 140 may also output flood illumination in accordance with instructions from the DCA controller 150. For flood illumination, the SL VCSEL array and the fill VCSEL array are instructed (by the DCA controller 150) to both emit light. The light from the fill VCSEL array is spread by the cylindrical lens to form a second pattern. And due to positioning of the fill VCSEL array, the generated second pattern functions to fill in the dark spaces of the first linear SL pattern generated by the SL VCSEL array, thereby, forming flood illumination.

In some embodiments, the optical assembly may tile the light emitted by the VCSEL chip, such that a linear SL pattern or flood illumination emitted by the VCSEL chip is tiled across different portion of the local area. For example, the optical assembly may include one or more diffraction gratings that tile the light emitted from the VCSEL chip. And in some embodiments, the optical assembly may include a steerable mirror or some other optical element to dynamically directionalize light, thereby providing additional selectivity of where the linear SL pattern or flood illumination is projected in the local area.

The camera assembly capture images of the local area illuminated with light from the VCSEL chip. The camera assembly includes one or more imaging devices 130 (e.g., cameras).

The DCA controller 150 calculates depth information based on the images captured by the imaging devices 130 and the depth sensing mode. For example, if the DCA controller 150 had instructed the illuminator 140 to emit a linear SL pattern, the DCA controller 150 would use a SL depth sensing mode and the captured images to determine depth for the portion of the local area illuminated with the linear SL pattern. The DCA controller 150 may determine depth to an object in the local area using an initial depth sensing mode, such as TOF, then, based on a calculated depth to the object, the DCA controller 150 may select some or all of the SL VCSEL array for activation in order to illuminate the portion of the local area containing the object while not illuminating other areas of the local area. The depth information may be used by other components (e.g., the audio system, the display assembly, an application, etc.) to facilitate presenting content to the user.

The audio system provides audio content. The audio system includes a transducer array, a sensor array, and an audio controller. However, in other embodiments, the audio system may include different and/or additional components. Similarly, in some cases, functionality described with reference to the components of the audio system can be distributed among the components in a different manner than is described here. For example, some or all of the functions of the controller may be performed by a remote server.

The transducer array presents sound to user. The transducer array includes a plurality of transducers. A transducer may be a speaker 160 or a tissue transducer 170 (e.g., a bone conduction transducer or a cartilage conduction transducer). Although the speakers 160 are shown exterior to the frame 110, the speakers 160 may be enclosed in the frame 110. In some embodiments, instead of individual speakers for each ear, the headset 100 includes a speaker array comprising multiple speakers integrated into the frame 110 to improve directionality of presented audio content. The tissue transducer 170 couples to the head of the user and directly vibrates tissue (e.g., bone or cartilage) of the user to generate sound. The number and/or locations of transducers may be different from what is shown in FIG. 1A.

The sensor array detects sounds within the local area of the headset 100. The sensor array includes a plurality of acoustic sensors 180. An acoustic sensor 180 captures sounds emitted from one or more sound sources in the local area (e.g., a room). Each acoustic sensor is configured to detect sound and convert the detected sound into an electronic format (analog or digital). The acoustic sensors 180 may be acoustic wave sensors, microphones, sound transducers, or similar sensors that are suitable for detecting sounds.

In some embodiments, one or more acoustic sensors 180 may be placed in an ear canal of each ear (e.g., acting as binaural microphones). In some embodiments, the acoustic sensors 180 may be placed on an exterior surface of the headset 100, placed on an interior surface of the headset 100, separate from the headset 100 (e.g., part of some other device), or some combination thereof. The number and/or locations of acoustic sensors 180 may be different from what is shown in FIG. 1A. For example, the number of acoustic detection locations may be increased to increase the amount of audio information collected and the sensitivity and/or accuracy of the information. The acoustic detection locations may be oriented such that the microphone is able to detect sounds in a wide range of directions surrounding the user wearing the headset 100.

An audio controller processes information from the sensor array that describes sounds detected by the sensor array. The audio controller may comprise a processor and a computer-readable storage medium. The audio controller may be configured to generate direction of arrival (DOA) estimates, generate acoustic transfer functions (e.g., array transfer functions and/or head-related transfer functions), track the location of sound sources, form beams in the direction of sound sources, classify sound sources, generate sound filters for the speakers 160, or some combination thereof.

The position sensor 190 generates one or more measurement signals in response to motion of the headset 100. The position sensor 190 may be located on a portion of the frame 110 of the headset 100. The position sensor 190 may include an inertial measurement unit (IMU). Examples of position sensor 190 include: one or more accelerometers, one or more gyroscopes, one or more magnetometers, another suitable type of sensor that detects motion, a type of sensor used for error correction of the IMU, or some combination thereof. The position sensor 190 may be located external to the IMU, internal to the IMU, or some combination thereof.

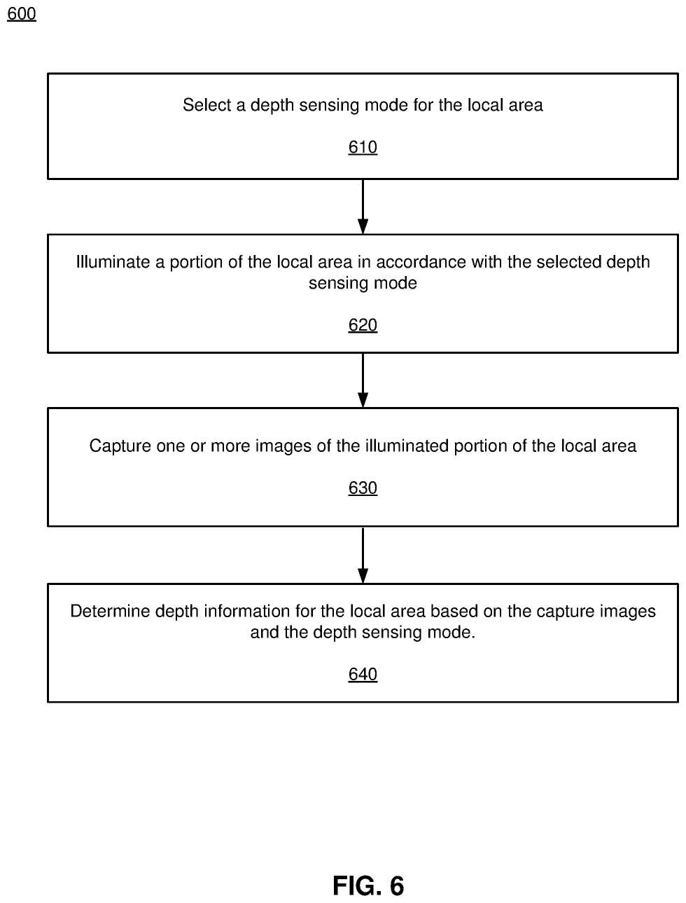

In some embodiments, the headset 100 may provide for simultaneous localization and mapping (SLAM) for a position of the headset 100 and updating of a model of the local area. For example, the headset 100 may include a passive camera assembly (PCA) that generates color image data. The PCA may include one or more RGB cameras that capture images of some or all of the local area. In some embodiments, some or all of the imaging devices 130 of the DCA may also function as the PCA. The images captured by the PCA and the depth information determined by the DCA may be used to determine parameters of the local area, generate a model of the local area, update a model of the local area, or some combination thereof. Furthermore, the position sensor 190 tracks the position (e.g., location and pose) of the headset 100 within the room. Additional details regarding the components of the headset 100 are discussed below in connection with FIG. 6.

FIG. 1B is a perspective view of a headset 105 implemented as a HMD, in accordance with one or more embodiments. In embodiments that describe an AR system and/or a MR system, portions of a front side of the HMD are at least partially transparent in the visible band (˜380 nm to 750 nm), and portions of the HMD that are between the front side of the HMD and an eye of the user are at least partially transparent (e.g., a partially transparent electronic display). The HMD includes a front rigid body 115 and a band 175. The headset 105 includes many of the same components described above with reference to FIG. 1A, but modified to integrate with the HMD form factor. For example, the HMD includes a display assembly, a DCA, an audio system, and a position sensor 190. FIG. 1B shows the illuminator 140, the DCA controller 150, a plurality of the speakers 160, a plurality of the imaging devices 130, a plurality of acoustic sensors 180, and the position sensor 190. The illuminator 140 is configured to generate linear SL patterns and/or flood illumination for depth sensing.

FIG. 2 is a block diagram of a DCA 200, in accordance with one or more embodiments. The DCA of FIG. 1A and FIG. 1B may be an embodiment of the DCA 200. The DCA 200 is configured to obtain depth information of a local area surrounding the DCA 200. For example, the DCA 200 may be configured to detect the location of objects in a room. The DCA 200 comprises an illuminator 210, a camera assembly 220, and a DCA controller 230. Some embodiments of the DCA 200 have different components than those described here. Similarly, in some cases, functions can be distributed among the components in a different manner than is described here.

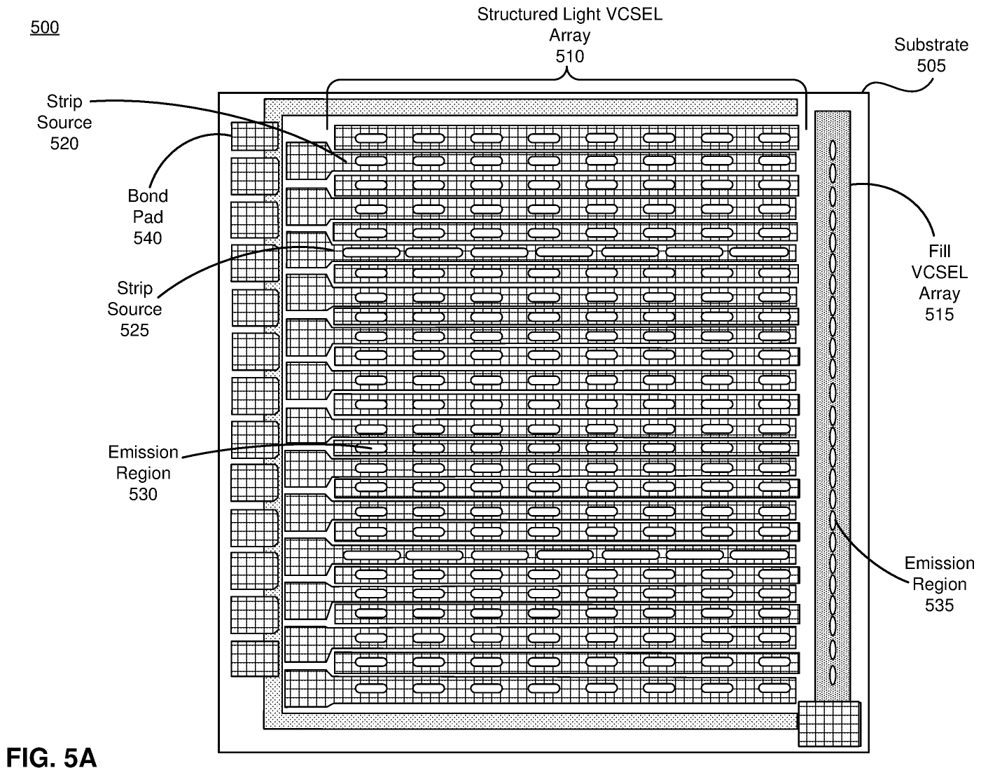

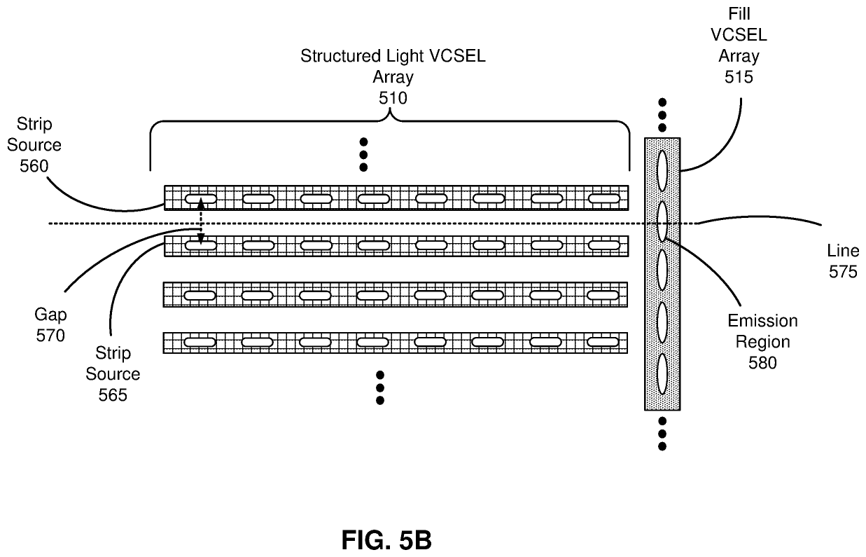

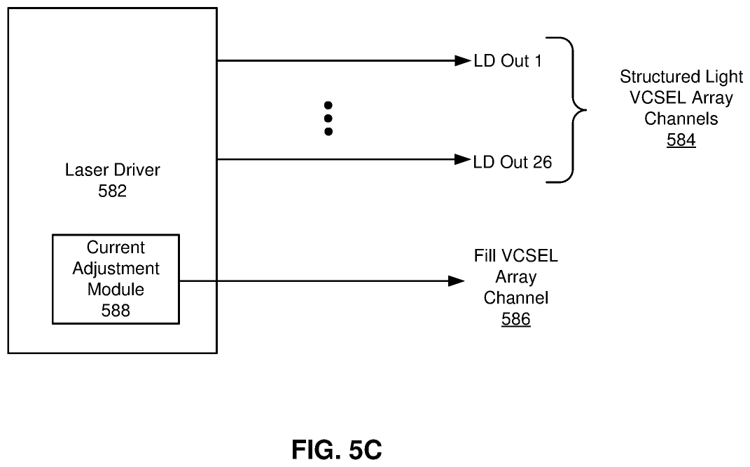

The illuminator 210 is configured to project light into the local area. The illuminator 140 of FIG. 1A and FIG. 1B may be an embodiment of the illuminator 210. The illuminator 210 may project one or more different linear SL patterns or flood illumination into a local area. The projected light may be in the IR. The illuminator 210 comprises a VCSEL chip and an optical assembly. An example VCSEL chip is described below with regard to FIG. 5.

The VCSEL chip emits light for the generation of the one or more SL patterns or flood illumination. The VCSEL chip includes a plurality of VCSEL arrays on a substrate. The plurality of VCSEL arrays includes one or more linear SL VCSEL arrays and one or more fill VCSEL arrays. Each of the VCSELs of the plurality of VCSEL arrays have a respective emission region of a particular size and shape. An emission region may have a shape of, e.g., a rectangle, an oval, a diamond, a triangle, a square, a sinusoidal, etc.

The one or more linear SL VCSEL arrays are configured to generate the one or more different types of linear SL patterns. Each linear SL VCSEL array includes one or more strip sources. A strip source is a plurality of VCSELs arranged in a linear manner, and each of the VCSELs has a respective emission region. In some embodiments, the VCSELs of a strip source have emission regions of a same size and/or a same shape (e.g., rectangle with a same length). In other embodiments, the VCSELs of a strip source have emission regions of different shapes and/or sizes. In some embodiments, one or more linear SL VCSEL arrays include some strip sources composed of VCSELs that have emission regions of a first length (e.g., a rectangle with a long dimension being the first length), and one or more other strip sources composed of VCSELs that have emission regions of a second length that is longer than the first length. For example, a strip source with VCSELs having longer emission areas may be interleaved between strip sources with VCSELS having shorter emission areas. The strip sources with VCSELs of longer emission areas may be interposed periodically or periodically between or adjacent to the rows of strips sources with VCSELs having emission areas of shorter lengths. VCSELs with longer emission regions emit more light than VCSELs with shorter emission regions. For example, rows (e.g., strip sources) of VCSELs with longer emission areas in one linear SL VCSEL array may be used for determining depth in the far field, and rows of VCSELs with shorter emission areas in another linear SL VCSEL array may be used for determining depth in the near field. Note that the strip sources of each of the one or more SL VCSEL arrays are arranged in parallel. Accordingly, adjacent strip sources are separated by a gap (i.e., pitch). This gap corresponds to a dim region between bar in the linear SL pattern that is ultimately formed. Likewise, light emitted from a strip source corresponds to a bar in the linear SL pattern. Some or all of the strip sources of the one or more linear SL VCSEL arrays are addressable. For example, in some embodiments, all of the strip sources are addressable.

The one or more fill VCSEL arrays are used in combination with one or more of the SL VCSEL arrays to generate flood illumination. The one or more fill VCSEL arrays are arranged orthogonally on the substrate to the one or more SL VCSEL arrays. Each of the one or more fill VCSEL arrays includes one or more strip sources arranged in parallel, and each strip source includes a plurality of VCSELs arranged in a linear manner. A given VCSEL of a fill arrays may emit more light than a given VCSEL of a SL VCSEL array. In some embodiments, the VCSELs of a fill VCSEL array have emission regions of a same size and/or shape (e.g., oval). In other embodiments, the VCSELs of a fill VCSEL array have emission regions of different shapes and/or sizes. The emission regions of VCSELs in the one or more SL VCSEL arrays are arranged such that light they produce can be used to fill in dim regions in a linear SL pattern produced by the one or more SL VCSEL arrays. For example, adjacent strip sources of the one or more SL VCSEL arrays are parallel to each other and are separated by respective gaps that each have a respective region that corresponds to a minimum light intensity in the dim region of the bar pattern. And for each gap there is a corresponding VCSEL of the one or more fill VCSEL arrays that has its emission region positioned along a line parallel to the adjacent strip sources that passes within a threshold distance (and potentially through) the corresponding region of minimum light intensity. Note in some embodiments, the region may be in a center of the gap (e.g., if the adjacent strip sources each emit a same intensity of light). But in some instances, the region may be offset from the center of the gap (e.g., if one of the adjacent strip sources emits light at substantially different intensity than the other adjacent strip source). In some embodiments, to produce flood illumination of a more even intensity distribution, sizes and/or shapes of emission regions of VCSELs in the one or more SL VCSEL arrays may vary to account for variations in light emitted from different sizes and/or shapes of emission areas of VCSELs in the one or more SL VCSEL arrays.

The intensity of light emitted by a VCSEL may be in part based on an area of the emission region of the VCSEL. The far field VCSELs comprising relatively long lengths may emit light at a greater intensity than the near field VCSELs comprising emission regions of relatively short lengths. The far field VCSELs may be activated for depth sensing in the far field, where a higher intensity of illumination is desired. The near field VCSELs may be activated for depth sensing in the near field, where DCA 200 may utilize a lower intensity illumination. As used herein, the “far field” refers to distances greater than a threshold distance from the DCA 200. As used herein, the “near field” refers to distances less than the threshold distance from the DCA 200. In some embodiments, the threshold distance may be approximately 2 meters, or between 1-5 meters.

The optical assembly is configured to condition the light emitted by the VCSEL array. The optical assembly may comprise one or more lenses, apertures, diffractive optical elements, or some combination thereof. The conditioning of the light includes stretching the light emitted by each VCSEL. For example, the one or more lenses may include a cylindrical lens that substantially applies optical power in one axis, but does not apply optical power in the orthogonal axis. In this manner, the cylindrical lens may be used to spread light (in substantially a single dimension) emitted by an emission region of a VCSEL. The cylindrical lens may be oriented such that the optical power is applies spreads the light in a long dimension of each strip source of the one or more SL VCSEL arrays, thereby causing discrete points of light to merge into one another to form a series of parallel bars, where each bar corresponds to light emitted from a different strip source. In this manner the cylindrical lens may be used to form a linear SL pattern from light emitted by the one or more SL VCSEL arrays. Note that a line of the linear SL pattern may have a constant intensity or a substantially constant intensity along the length of the line. In some embodiments, the one or more lenses may include additional filters to facility smoothing intensity over the length of a line.

In a similar manner, light emitted from the one or more fill VCSEL arrays is spread in the same dimension. Note that the one or more fill VCSEL arrays are positioned orthogonal to the one or more SL VCSEL arrays, and that the emission regions of the one or more fill VCSEL arrays are positioned in line with gaps between adjacent strip sources of the one or more SL VCSEL arrays. Accordingly, the light emitted from the one or more fill VCSEL arrays are spread by the cylindrical lens to form a second pattern. And in cases where the one or more SL VCSEL arrays are generating a linear SL pattern, due to positioning of the one or more fill VCSEL arrays relative to the one or more SL linear VCLSEL arrays, the generated second pattern functions to fill in the dim regions of the linear SL pattern, thereby, forming flood illumination. In some embodiments, the one or more lenses may include additional filters to facility generating a smooth and even intensity of the flood illumination over its field of illumination.

The conditioning of the light may also include tiling the light (SL pattern or flood illumination) emitted by the VCSEL chip over a portion of the local area. The illuminator 210 has a field of illumination that spans a portion of the local area of the DCA 200. The optical assembly may tile the emitted light using, e.g., one or more diffraction gratings, in order to increase the field of illumination of the illuminator 210. The diffraction gratings may be, e.g., 1D for tiling in one dimension, or 2D for tiling in 2 dimensions. In this manner, e.g., a linear SL pattern or flood illumination may be replicated and projected into the local area to illuminate a larger portion of the local area.

The camera assembly 220 is configured to capture light from the local area in accordance with instructions from the DCA controller 230. The camera assembly 220 includes one or more imaging devices (e.g., the imaging devices 130 of FIG. 1A and FIG. 1B). Each imaging device (e.g., camera) may comprise one or more sensors. In some embodiments, each sensor may comprise a charge-coupled device (CCD) or a complementary metal-oxide-semiconductor (CMOS). Each sensor comprises a plurality of pixels. Each pixel is configured to detect photons incident on the pixel. The pixels are configured to detect a bandwidth of light including the wavelength of the light projected by the illuminator 210.

The DCA controller 230 is configured to provide instructions to the various components of the DCA 200 and calculate depth information for the local area. The DCA controller 150 of FIG. 1A and FIG. 1B may be an embodiment of the DCA controller 230. Some embodiments of the DCA controller 230 have different components than those described here. Similarly, in some cases, functions can be distributed among the components in a different manner than is described here.

The DCA controller 230 is configured to generate instructions for the illuminator 210 to emit light into the local area. The DCA controller 230 selects a depth sensing mode. The depth sensing mode is selected based on, e.g., a predefined pattern (e.g., five SL frames that are followed by flood illumination frame), scene content (e.g., use of SL for close objects, and TOF for objects that are far away), etc. The DCA controller 230 instructs the illuminator 210 to illuminate a portion of the local area in accordance with the selected depth sensing mode. For example, if the depth sensing mode is assisted stereo or SL, the DCA controller 230 instructs the illuminator 210 to emit a linear SL pattern. Likewise, if the depth sensing mode is TOF, the DCA controller 230 instructs the illuminator 210 to emit flood illumination. In some embodiments, the DCA controller 230 may identify particular regions in the local area to track and instruct the illuminator 210 to selectively illuminate the identified regions. And in some embodiments, the DCA controller 230 may generate and provide instructions to the illuminator 210 to illuminate an object in the near field, and the illuminator 210 would illuminate the object using strip sources having VCSELs with relatively short emission regions. And in some embodiments, the DCA controller 230 may generate and provide instructions to the illuminator 210 to illuminate an object in the far field, and the illuminator 210 would illuminate the object using strip sources having VCSELs with relatively long emission regions.

The DCA controller 230 generates and provides instructions to the camera assembly 220 to capture images of the illuminated portion (i.e., with a linear SL pattern or flood illumination) of the local area in accordance with the selected depth sensing mode.

The DCA controller 230 calculates depth information based on the images captured by the camera assembly 220 of the illuminated portion of the local area and the selected depth determination mode. The depth information may be calculated using a variety of depth sensing modes, including TOF depth sensing (may be direct TOF or indirect TOF), SL depth sensing, passive stereo depth sensing, assisted stereo depth sensing, stereo imaging, or some combination thereof. The DCA controller 230 may store the depth information in a model of the local area. The model describing size and shapes of objects and the positions of those objects in the local area.

The DCA controller 230 may dynamically adjust which bars are active in the linear SL pattern. For example, the DCA controller 230 may control a line density of the bars in the linear SL pattern, periodicity (or aperiodicity) of the bars in the linear SL pattern, or some combination thereof. The DCA controller 230 may adjust the pattern based on, e.g., distance of object from the DCA 200, object type (e.g., dense pattern for hands of the user v. sparse pattern for a wall), movement of the object relative to the DCA 200 (e.g., a denser pattern may be used for a moving object than for a static object).

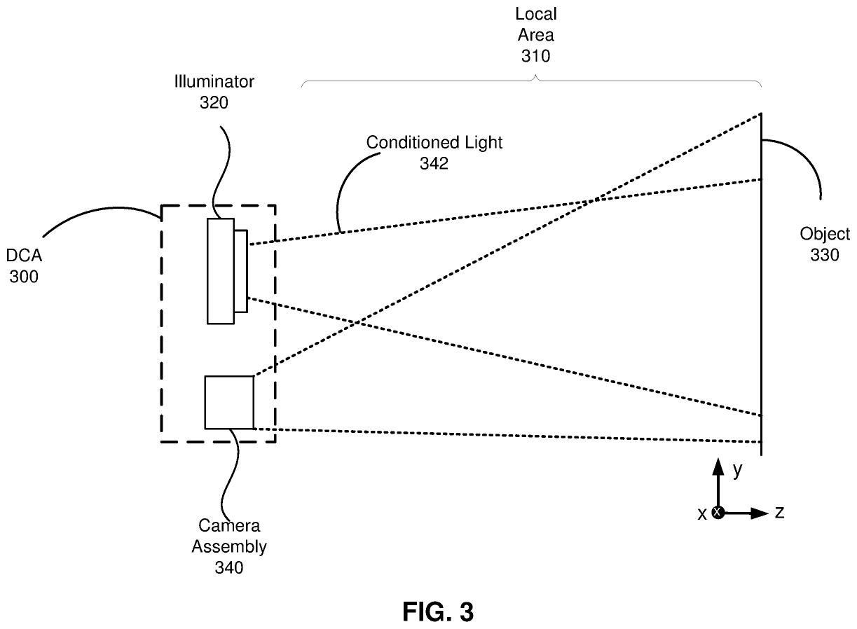

FIG. 3 is a schematic diagram of a DCA 300 obtaining depth information in a local area 310, in accordance with one or more embodiments. The DCA 300 may be an embodiment of the DCA 200 of FIG. 2. The DCA 300 comprises an illuminator 320 and a camera assembly 340. The illuminator 320 may be an embodiment of the illuminator 210 of FIG. 2, and the camera assembly 340 is an embodiment of the camera assembly 220. The illuminator 320 conditions light (via an optical assembly) from a VCSEL chip to produce conditioned light (e.g., a linear SL pattern or flood illumination). The DCA 300 may illuminate some or all of an object 330 with conditioned light 342.

The camera assembly 340 captures images of the object 330 illuminated with the conditioned light 342. As illustrated a field of illumination (FOI) of the illuminator 320 is smaller than a field of view (FOV) of the camera assembly 340. But in other embodiments, the FOI may have a different size relative to the FOV, and in some cases may be larger than the FOV. In some embodiments, the illuminator 320 is able to dynamically change its FOI by, e.g., adjusting how much of and where tiling of the conditioned light 342 occurs within the local area 310. As described above with reference to FIG. 2, a controller (not shown) of the DCA 300 determines depth information for the local area 310 using the captured images.

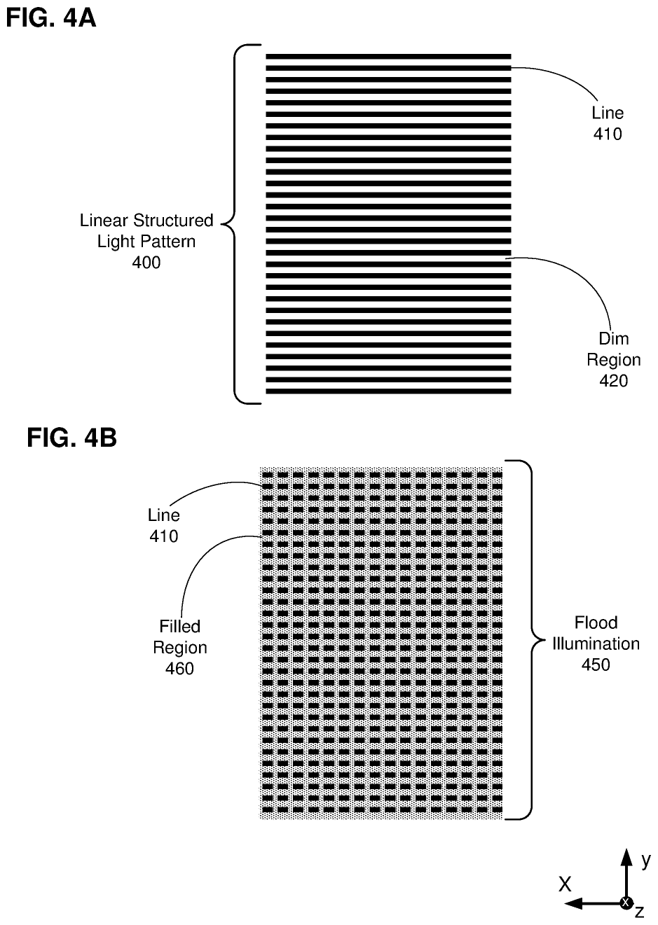

FIG. 4A is a plan view of a linear SL pattern 400, in accordance with one or more embodiments. The linear SL pattern 400 includes a plurality of lines (e.g., line 410) that are arranged in parallel to form a bar pattern. Each line of the plurality of lines is formed from light from a single strip source (e.g., of the one or more SL linear VCLSEL arrays). Between adjacent lines in the linear SL pattern 400 there are respective dim regions (e.g., dim region 420). In some embodiments, a DCA may tile the linear SL pattern 400 to cover a larger portion of the local area.

FIG. 4B is a plan view of flood illumination, in accordance with one or more embodiments. The flood illumination 450 is formed by having both the one or more SL linear VCLSEL arrays and the one or more fill VCSEL arrays emit light at a same time. The one or more SL VCSEL arrays generate a linear SL pattern and the one or more fill VCSEL arrays generate a second pattern. The second pattern is positioned such that it fills in the dim regions with light to form filled regions (e.g., filled region 460). Accordingly, the SL linear pattern and the second pattern together form the flood illumination 450. In some embodiments, a DCA may tile the flood illumination 450 to cover a larger portion of the local area.

FIG. 5A is a plan view of a VCSEL chip 500, in accordance with one or more embodiments. The VCSEL chip 500 may be an embodiment of a VCSEL chip of the illuminator 210 of FIG. 2. The VCSEL chip 500 may comprise a substrate 505, a SL VCSEL array 510, a fill VCSEL array 515, and a plurality of bond pads.

The substrate 505 is configured to provide a surface on which the various components of the VCSEL chip 500 may be assembled.

The SL VCSEL array 510 is configured to generate one or more different linear SL patterns. The linear SL pattern array includes a plurality of strip sources (e.g., strip source 520 and strip source 525). In the illustrated embodiment, the plurality of strip sources are arranged substantially parallel to each other on the substrate 505. While the VCSEL chip 500 as illustrated includes 26 strip sources, in other embodiments, the number of strip sources may be more or less. As shown, each of the strip sources are individually addressable. In this manner the SL VCSEL array 510 may activate any of the strip sources to produce a variety of bar patterns. For example, a high density pattern may be achieved by activating all of the strip sources, and low density bar pattern may be achieved by activating every fifth strip source.

Each strip source includes a plurality of VCSELs, and each VCSEL includes a respective emission region (e.g., emission region 530). In FIG. 5A, each strip source includes VCSELs with emission regions of the same size and shape, but in other embodiments, one or more emission regions of VCSELs on a single strip source may vary in size and/or shape. Note that some of the strip sources include VCSELs with emission regions that are larger than emission regions in other strip sources. For example, the emission regions in the strip source 525 are larger than the emission regions in the strip source 520. The strip sources (e.g., 525) with larger emission regions emit more light than the strip sources (e.g., 520) with the smaller emission regions. As illustrated the emission regions are all a substantially rectangular shape, but in other embodiments, the emission regions may have different shapes.

The fill VCSEL array 515 is configured to emit a second pattern of light. As illustrated the fill VCSEL array 515 is a single strip source. However, in some embodiments, the fill VCSEL array 515 may include a plurality of strip sources. The fill VCSEL array 515 is arranged orthogonally on the substrate relative to the SL VCSEL array 510. As illustrated, the fill VCSEL array 515 includes a single strip source that includes a plurality of VCSELs arranged in a linear manner, and each of the VCSELs includes a respective emission region 535. As shown the fill VCSEL array is located on a first side (i.e., right) of SL VCSEL array 510, but in other embodiments, the fill VCSEL array may be located elsewhere on the chip. For example, the fill VCSEL array may be located on the other side (e.g., left) of the SL VCSEL array, located in a center of the SL VCSEL array, etc. Additionally, in some embodiments, there may be multiple fill VCSEL arrays on the VCSEL chip. For example, there may be a plurality of fill VCSEL arrays that are adjacent to parallel to and next to each other. Or in other embodiments, there may be fill VCSEL chips located in different positions relative to the SL VCSEL array 510 (e.g., one fill VCSEL array to the left of the SL VCSEL array, and a second fill VCSEL array to the right of the SL VCSEL array). The emission regions of the fill VCSEL array 515 are offset from the individual strip sources of the SL VCSEL array 510. This is described in detail below with regard to FIG. 5B. Note that in light from a VCSEL in the fill VCSEL array 515 may be brighter than the light of a VCSEL in the SL VCSEL array 510. The brightness of the VCSEL in the fill VCSEL array 510 may be determined in order to have flood illumination with a substantially flat intensity profile.

The light from the fill VCSEL array is spread by an optical assembly of the DCA to form a second pattern. And due to positioning of the fill VCSEL array, the generated second pattern functions to fill in the dim regions of the SL pattern emitted by the SL VCSEL array 510, thereby, forming flood illumination.

The bond pads (e.g., bond pad 540) are configured to provide an electrical connection between the substrate 510 and the strip sources. The bond pads may comprise an electrically conductive material coupled to the substrate 510. As illustrated the bond pads and the corresponding strip sources of the SL VCSEL array 510 are generally interleaved to provide for a compact form factor.

FIG. 5B is a portion of the VCSEL chip 500 of FIG. 5A. The strip sources of the SL VCSEL array 510 are parallel to each other and are separated by respective gaps (also referred to as pitch). For example, the SL VCSEL array 510 includes strip source 560 and strip source 565, and they are separated by a gap 570 (may also be referred to as pitch). As illustrated the gap between the various strip sources is constant, but in some embodiments, the gap may be different for one or more adjacent strip sources. Note that for each gap there is a corresponding emission region of a VCSEL of the fill VCSEL array 515 that is positioned offset from the strip sources such that the emission region is in line with a corresponding gap. For example, a line 575 is parallel to and between the strip sources 560 ,565, and the line 575 runs through the gap 570 and intersects with a center of an emission region 580 of a VCSEL of the fill VCSEL array 515. As illustrated the line 575 corresponds to a region of minimum light intensity between the light emitted from the strip source 560 and the strip source 565 (i.e., a dim region between bars of light in the SL pattern). As illustrated the line 575 is positioned along a center of the gap. But in other embodiments, the line 575 may be offset from the center of the gap 570. For example, if one of the adjacent strip sources emits light at substantially different intensity than the other adjacent strip source.

FIG. 5C is an example current driver 582 for the VCSEL chip 500 of FIG. 5A. The current driver 582 selectively provides current to one or more of SL VCSEL array channels 584 and/or a fill VCSEL array channel 586. The SL VCSEL array channels include a current channel for each strip source of the SL VCSEL array 510, and the fill VCSEL array channel 586 includes a current channel for the single strip source of the fill VCSEL array 515. Note that in other embodiments, there may be multiple strip sources in the fill VCSEL array and/or multiple fill VCSEL arrays, as such there may be more than one fill VCSEL array channel in other embodiments. The current channels provide current which is used to drive VCSELs in the SL VCSEL array 510 and/or the fill VCSEL array 515. The laser driver 582 includes one or more current adjustment modules (e.g., current adjustment module 588).

The current adjustment module 588 may dynamically adjust current provided to the fill VCSEL array 515 in accordance with instructions from a controller (e.g., the controller 230). The current adjustment module 588 includes one or more digital analog controllers (DACs), and may also include, e.g., a current divider that is able to dynamically reduce the amount of current output on the fill VCSEL array channel 586 relative to current output on the SL VCSEL array channels 584. The one or more DACs provide independent control of each of the channels in the SL VCSEL array channels 584, the fill VCSEL array channel 586, or both. The amount of reduction may range between 1 (no reduction) and N (max amount of reduction). And N may be relatively large. For example, a N may be, 5, 8, 10 etc. For example, if the current adjustment module 588 is reducing current by a factor of 10, then it would output 1/10the amount of current on the fill VCSEL array channel 586 relative to the current output on one of the SL VCSEL array channels 584. In some embodiments, the range of reduction may be a continuous range. Alternatively, the range of reduction includes a series of discrete values. One advantage of being able to independently drive the fill VCSEL array 515 at a much lower current is safety. For example, the illuminator may also include a light sensor that is positioned to detect back scatter (e.g., from optical elements of the illuminator) of light emitted from the fill VCSEL array 515 and/or the SL VCSEL array 510. The current adjust module 588 may be instructed to reduce the current output on the fill VCSEL array channel 586. The amount of reduction may be relatively large relative to normal operation (e.g., factor of 10). The low current causes the FILL VCSEL array 515 to emit at a lower intensity than it would at normal operation. For example, the light sensor may be used to detect backscatter of light that is indicative of misalignment, damaged optics, etc. The illuminator may use the lower intensity emission and the signal from the light sensor as a safety check prior to, e.g., outputting a linear SL pattern or flood illumination at a high power from the VCSEL chip. This can act as safety check in case of misalignment, damaged optics, etc. that could cause a safety hazard and/or potentially further damage the DCA. Additionally, the ability to dynamically adjust the drive current provides the DCA with an option for adjustable illumination of the fill VCSEL array 515.

Note that conventional laser drivers are not able to have a large delta between current supplied on different channels as it results in instability of the supplied current. This is in part because conventional laser drivers are unable to independently control current supplied to different channels. Instead a global DAC may be used that provides uniform current control across all of their channels. In contrast, the current adjustment module 588 is able to independently control each of the channels in the SL VCSEL array channels 584, the fill VCSEL array channel 586, or both.

As illustrated the current adjustment module 588 is adjusting current supplied to the fill VCSEL array channel 586. In other embodiments, the current adjustment module 588 and/or one or more additional current adjustment modules may adjust current provided one some or all channels, e.g., some or all of SL VCSEL array channels, some or all fill VCSEL array channels, or some combination thereof.

FIG. 6 is a flowchart illustrating a process 600 for generating a linear SL pattern or flood illumination, in accordance with one or more embodiments. The process shown in FIG. 6 may be performed by components of a DCA (e.g., DCA 200 of FIG. 2). Other entities may perform some or all of the steps in FIG. 6 in other embodiments. Embodiments may include different and/or additional steps or perform the steps in different orders.

The DCA selects 610 a depth sensing mode. For example, TOF may be used in bright light, and SL may be used indoors. Note in other embodiments, the depth sensing modes may be used in other conditions. The DCA instructs a VCSEL chip to emit light in accordance with the selected depth sensing mode.

The DCA illuminates 620 a portion of the local area in accordance with the selected depth sensing mode. For example, if the selected depth sensing mode was SL, then the DCA illuminates the portion of the local area with a linear SL pattern. Or, if the selected depth sensing is TOF, the DCA illuminates the portion of the local area with flood illumination. The DCA generates the linear SL pattern or the flood illumination using a VCSEL chip within an illuminator of the DCA.

The DCA captures 630 one or more images of the illuminated portion of the local area. The DCA captures the images using one or more imaging devices of a camera assembly.

The DCA determines 640 depth information for the local area based on the captured images. The DCA uses the captured images and the selected depth sensing mode to calculate the depth information. The DCA updates a model with the determined depth information.

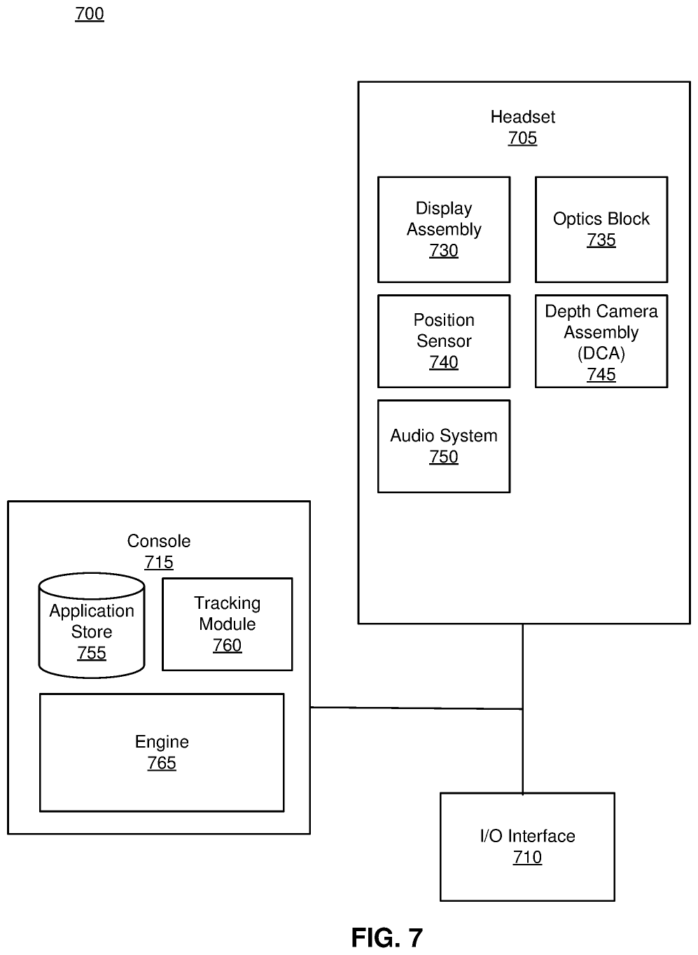

FIG. 7 is a system 700 that includes a headset 705, in accordance with one or more embodiments. In some embodiments, the headset 705 may be the headset 100 of FIG. 1A or the headset 105 of FIG. 1B. The system 700 may operate in an artificial reality environment (e.g., a virtual reality environment, an augmented reality environment, a mixed reality environment, or some combination thereof). The system 700 shown by FIG. 7 includes the headset 705 and an input/output (I/O) interface 710 that is coupled to a console 715. While FIG. 7 shows an example system 700 including one headset 705 and one I/O interface 710, in other embodiments any number of these components may be included in the system 700. For example, there may be multiple headsets each having an associated I/O interface 710, with each headset and I/O interface 710 communicating with the console 715. In alternative configurations, different and/or additional components may be included in the system 700. Additionally, functionality described in conjunction with one or more of the components shown in FIG. 7 may be distributed among the components in a different manner than described in conjunction with FIG. 7 in some embodiments. For example, some or all of the functionality of the console 715 may be provided by the headset 705.

The headset 705 includes the display assembly 730, an optics block 735, one or more position sensors 740, and the DCA 745. Some embodiments of headset 705 have different components than those described in conjunction with FIG. 7. Additionally, the functionality provided by various components described in conjunction with FIG. 7 may be differently distributed among the components of the headset 705 in other embodiments or be captured in separate assemblies remote from the headset 705.

The display assembly 730 displays content to the user in accordance with data received from the console 715. The display assembly 730 displays the content using one or more display elements (e.g., the display elements 120). A display element may be, e.g., an electronic display. In various embodiments, the display assembly 730 comprises a single display element or multiple display elements (e.g., a display for each eye of a user). Examples of an electronic display include: a liquid crystal display (LCD), an organic light emitting diode (OLED) display, an active-matrix organic light-emitting diode display (AMOLED), a waveguide display, some other display, or some combination thereof. Note in some embodiments, the display element 120 may also include some or all of the functionality of the optics block 735.

The optics block 735 may magnify image light received from the electronic display, corrects optical errors associated with the image light, and presents the corrected image light to one or both eyeboxes of the headset 705. In various embodiments, the optics block 735 includes one or more optical elements. Example optical elements included in the optics block 735 include: an aperture, a Fresnel lens, a convex lens, a concave lens, a filter, a reflecting surface, or any other suitable optical element that affects image light. Moreover, the optics block 735 may include combinations of different optical elements. In some embodiments, one or more of the optical elements in the optics block 735 may have one or more coatings, such as partially reflective or anti-reflective coatings.

Magnification and focusing of the image light by the optics block 735 allows the electronic display to be physically smaller, weigh less, and consume less power than larger displays. Additionally, magnification may increase the field of view of the content presented by the electronic display. For example, the field of view of the displayed content is such that the displayed content is presented using almost all (e.g., approximately 110 degrees diagonal), and in some cases, all of the user's field of view. Additionally, in some embodiments, the amount of magnification may be adjusted by adding or removing optical elements.

In some embodiments, the optics block 735 may be designed to correct one or more types of optical error. Examples of optical error include barrel or pincushion distortion, longitudinal chromatic aberrations, or transverse chromatic aberrations. Other types of optical errors may further include spherical aberrations, chromatic aberrations, or errors due to the lens field curvature, astigmatisms, or any other type of optical error. In some embodiments, content provided to the electronic display for display is pre-distorted, and the optics block 735 corrects the distortion when it receives image light from the electronic display generated based on the content.

The position sensor 740 is an electronic device that generates data indicating a position of the headset 705. The position sensor 740 generates one or more measurement signals in response to motion of the headset 705. The position sensor 190 is an embodiment of the position sensor 740. Examples of a position sensor 740 include: one or more IMUs, one or more accelerometers, one or more gyroscopes, one or more magnetometers, another suitable type of sensor that detects motion, or some combination thereof. The position sensor 740 may include multiple accelerometers to measure translational motion (forward/back, up/down, left/right) and multiple gyroscopes to measure rotational motion (e.g., pitch, yaw, roll). In some embodiments, an IMU rapidly samples the measurement signals and calculates the estimated position of the headset 705 from the sampled data. For example, the IMU integrates the measurement signals received from the accelerometers over time to estimate a velocity vector and integrates the velocity vector over time to determine an estimated position of a reference point on the headset 705. The reference point is a point that may be used to describe the position of the headset 705. While the reference point may generally be defined as a point in space, however, in practice the reference point is defined as a point within the headset 705.

The DCA 745 generates depth information for a portion of the local area. The DCA 745 may be an embodiment of the DCA 200 of FIG. 2. The DCA includes one or more imaging devices and a DCA controller. The DCA 745 also includes an illuminator including a VCSEL chip. The DCA 745 may be configured to generate different SL patterns and flood illumination for depth sensing using the VCSEL chip. The different SL patterns and flood illumination may be generated by activating different strip sources of the illuminator. Operation and structure of the DCA 745 is described above primarily with regard to FIG. 2.

The audio system 750 provides audio content to a user of the headset 705. The audio system 750 may comprise one or acoustic sensors, one or more transducers, and an audio controller. The audio system 750 may provide spatialized audio content to the user. In some embodiments, the audio system may request acoustic parameters from a mapping server. The acoustic parameters describe one or more acoustic properties (e.g., room impulse response, a reverberation time, a reverberation level, etc.) of the local area. The audio system 750 may provide information describing at least a portion of the local area from e.g., the DCA 745 and/or location information for the headset 705 from the position sensor 740. The audio system 750 may generate one or more sound filters using one or more of the acoustic parameters and use the sound filters to provide audio content to the user.

The I/O interface 710 is a device that allows a user to send action requests and receive responses from the console 715. An action request is a request to perform a particular action. For example, an action request may be an instruction to start or end capture of image or video data, or an instruction to perform a particular action within an application. The I/O interface 710 may include one or more input devices. Example input devices include: a keyboard, a mouse, a game controller, or any other suitable device for receiving action requests and communicating the action requests to the console 715. An action request received by the I/O interface 710 is communicated to the console 715, which performs an action corresponding to the action request. In some embodiments, the I/O interface 710 includes an IMU that captures calibration data indicating an estimated position of the I/O interface 710 relative to an initial position of the I/O interface 710. In some embodiments, the I/O interface 710 may provide haptic feedback to the user in accordance with instructions received from the console 715. For example, haptic feedback is provided when an action request is received, or the console 715 communicates instructions to the I/O interface 710 causing the I/O interface 710 to generate haptic feedback when the console 715 performs an action.

The console 715 provides content to the headset 705 for processing in accordance with information received from one or more of: the DCA 745, the headset 705, and the I/O interface 710. In the example shown in FIG. 7, the console 715 includes an application store 755, a tracking module 760, and an engine 765. Some embodiments of the console 715 have different modules or components than those described in conjunction with FIG. 7. Similarly, the functions further described below may be distributed among components of the console 715 in a different manner than described in conjunction with FIG. 7. In some embodiments, the functionality discussed herein with respect to the console 715 may be implemented in the headset 705, or a remote system.

The application store 755 stores one or more applications for execution by the console 715. An application is a group of instructions, that when executed by a processor, generates content for presentation to the user. Content generated by an application may be in response to inputs received from the user via movement of the headset 705 or the I/O interface 710. Examples of applications include: gaming applications, conferencing applications, video playback applications, or other suitable applications.

The tracking module 760 tracks movements of the headset 705 or of the I/O interface 710 using information from the DCA 745, the one or more position sensors 740, or some combination thereof. For example, the tracking module 760 determines a position of a reference point of the headset 705 in a mapping of a local area based on information from the headset 705. The tracking module 760 may also determine positions of an object or virtual object. Additionally, in some embodiments, the tracking module 760 may use portions of data indicating a position of the headset 705 from the position sensor 740 as well as representations of the local area from the DCA 745 to predict a future location of the headset 705. The tracking module 760 provides the estimated or predicted future position of the headset 705 or the I/O interface 710 to the engine 765.

The engine 765 executes applications and receives position information, acceleration information, velocity information, predicted future positions, or some combination thereof, of the headset 705 from the tracking module 760. Based on the received information, the engine 765 determines content to provide to the headset 705 for presentation to the user. For example, if the received information indicates that the user has looked to the left, the engine 765 generates content for the headset 705 that mirrors the user's movement in a virtual local area or in a local area augmenting the local area with additional content. Additionally, the engine 765 performs an action within an application executing on the console 715 in response to an action request received from the I/O interface 710 and provides feedback to the user that the action was performed. The provided feedback may be visual or audible feedback via the headset 705 or haptic feedback via the I/O interface 710.

A network couples the headset 705 and/or the console 715 to external systems. The network may include any combination of local area and/or wide area networks using both wireless and/or wired communication systems. For example, the network may include the Internet, as well as mobile telephone networks. In one embodiment, the network uses standard communications technologies and/or protocols. Hence, the network may include links using technologies such as Ethernet, 802.11, worldwide interoperability for microwave access (WiMAX), 2G/3G/4G mobile communications protocols, digital subscriber line (DSL), asynchronous transfer mode (ATM), InfiniBand, PCI Express Advanced Switching, etc. Similarly, the networking protocols used on the network can include multiprotocol label switching (MPLS), the transmission control protocol/Internet protocol (TCP/IP), the User Datagram Protocol (UDP), the hypertext transport protocol (HTTP), the simple mail transfer protocol (SMTP), the file transfer protocol (FTP), etc. The data exchanged over the network can be represented using technologies and/or formats including image data in binary form (e.g. Portable Network Graphics (PNG)), hypertext markup language (HTML), extensible markup language (XML), etc. In addition, all or some of links can be encrypted using conventional encryption technologies such as secure sockets layer (SSL), transport layer security (TLS), virtual private networks (VPNs), Internet Protocol security (IPsec), etc.

One or more components of system 700 may contain a privacy module that stores one or more privacy settings for user data elements. The user data elements describe the user or the headset 705. For example, the user data elements may describe a physical characteristic of the user, an action performed by the user, a location of the user of the headset 705, a location of the headset 705, an HRTF for the user, etc. Privacy settings (or “access settings”) for a user data element may be stored in any suitable manner, such as, for example, in association with the user data element, in an index on an authorization server, in another suitable manner, or any suitable combination thereof.

A privacy setting for a user data element specifies how the user data element (or particular information associated with the user data element) can be accessed, stored, or otherwise used (e.g., viewed, shared, modified, copied, executed, surfaced, or identified). In some embodiments, the privacy settings for a user data element may specify a “blocked list” of entities that may not access certain information associated with the user data element. The privacy settings associated with the user data element may specify any suitable granularity of permitted access or denial of access. For example, some entities may have permission to see that a specific user data element exists, some entities may have permission to view the content of the specific user data element, and some entities may have permission to modify the specific user data element. The privacy settings may allow the user to allow other entities to access or store user data elements for a finite period of time.

The privacy settings may allow a user to specify one or more geographic locations from which user data elements can be accessed. Access or denial of access to the user data elements may depend on the geographic location of an entity who is attempting to access the user data elements. For example, the user may allow access to a user data element and specify that the user data element is accessible to an entity only while the user is in a particular location. If the user leaves the particular location, the user data element may no longer be accessible to the entity. As another example, the user may specify that a user data element is accessible only to entities within a threshold distance from the user, such as another user of a headset within the same local area as the user. If the user subsequently changes location, the entity with access to the user data element may lose access, while a new group of entities may gain access as they come within the threshold distance of the user.

The system 700 may include one or more authorization/privacy servers for enforcing privacy settings. A request from an entity for a particular user data element may identify the entity associated with the request and the user data element may be sent only to the entity if the authorization server determines that the entity is authorized to access the user data element based on the privacy settings associated with the user data element. If the requesting entity is not authorized to access the user data element, the authorization server may prevent the requested user data element from being retrieved or may prevent the requested user data element from being sent to the entity. Although this disclosure describes enforcing privacy settings in a particular manner, this disclosure contemplates enforcing privacy settings in any suitable manner.

### Additional Configuration Information

The foregoing description of the embodiments has been presented for illustration; it is not intended to be exhaustive or to limit the patent rights to the precise forms disclosed. Persons skilled in the relevant art can appreciate that many modifications and variations are possible considering the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A vertical cavity surface emitting laser (VCSEL) chip comprising:
a first VCSEL array including a plurality of first VCSELs on a substrate;
a second VCSEL array including a plurality of second VCSELs on the substrate, the second VCSEL array positioned orthogonal to the first VCSEL array on the substrate, and
wherein light emitted from the first VCSEL array is used to form a bar pattern, and wherein light emitted from the first VCSEL array and the second VCSEL array together is used to form flood illumination.

2. The VCSEL chip of claim 1, wherein each of the plurality of first VCSELs have a respective emission region over a first length further comprising:
a third VCSEL array including a plurality of third VCSELs on the substrate, wherein each of plurality of third VCSELs have a respective emission region over a third length that is longer than the first length, and the third VCSEL array is oriented parallel to the first VCSEL array.

3. The VCSEL chip of claim 2, wherein at least a portion of the third VCSEL array is interleaved within the first VCSEL array.

4. The VCSEL chip of claim 1, wherein each of the second linear emission sources have an oval shaped emission area.

5. The VCSEL chip of claim 1, wherein two adjacent emission regions of the plurality second VCSELs are separated by a gap, and a first VCSEL of the first VCSEL array is positioned along a line that bisects the gap.

6. The VCSEL chip of claim 1, wherein the first VCSEL array is arranged as a plurality of parallel strip sources and each of the plurality of strip sources includes a plurality of first VCSELs.

7. The VCSEL chip of claim 6, wherein adjacent strip sources of the plurality of parallel strip sources are separated by respective gap, and for each gap there is a corresponding second VCSEL that has its emission region positioned along a line parallel to the adjacent strip sources that passes through a center of the gap.

8. The VCSEL chip of claim 6, wherein each of the plurality of strip sources is addressable, and wherein light from each of the plurality of strip sources corresponds to a different bar in the bar pattern.

9. The VCSEL chip of claim 8, wherein the second VCSEL array is arranged to form a single strip source that is addressable, and wherein light from the single strip source fills in dim regions between bars in the bar pattern to form the flood illumination.

10. The VCSEL chip of claim 1, wherein the light from the first VCSEL array is refracted by a cylindrical lens to form the bar pattern, and the light from the first VCSEL array and the second VCSEL array is refracted by the cylindrical lens to form the flood illumination.

11. The VCSEL chip of claim 1, wherein VCSEL chip is part of a depth camera assembly (DCA) and a controller of the DCA is configured to:
select a depth sensing mode for a local area of the DCA;
instruct the VCSEL chip to emit light in accordance with the selected depth determination technique; and
determine depth information for the local area using images captured of the local area that was illuminated with the emitted light from the VCSEL chip.

12. The VCSEL chip of claim 11, wherein the depth determination technique is selected from a group comprising: assisted stereo, time-of-flight, and structured light.

13. A depth camera assembly (DCA) comprising:
a vertical cavity surface emitting laser (VCSEL) chip comprising:
a first VCSEL array including a plurality of first VCSELs on a substrate,
a second VCSEL array including a plurality of second VCSELs on the substrate, the second VCSEL array positioned orthogonal to the first VCSEL array on the substrate;
an optical assembly configured to condition light from the VCSEL chip and project the conditioned light into a local area of the DCA, the conditioned light forming one of a bar pattern or flood illumination, wherein light emitted from the first VCSEL array is used to form the bar pattern, and wherein light emitted from the first VCSEL array and the second VCSEL array together is used to form the flood illumination;
a camera configured to capture images of the local area illuminated with the conditioned light; and
a controller configured to:
instruct the VCSEL chip to emit light in order to form one of the flood illumination or the bar pattern, and
determine depth information for the local area using the captured images.

14. The DCA of claim 13, wherein the controller is configured to:
select a depth sensing mode for the local area of the DCA, wherein the depth sensing mode is selected from a group comprising: assisted stereo, time-of-flight, and structured light; and
instruct the VCSEL chip to emit light in accordance with the selected depth sensing mode.

15. The DCA of claim 13, wherein each of the plurality of first VCSELs have a respective emission region over a first length, the DCA further comprising:
a third VCSEL array including a plurality of third VCSELs on the substrate, wherein each of plurality of third VCSELs have a respective emission region over a third length that is longer than the first length, and the third VCSEL array is oriented parallel to the first VCSEL array.

16. The DCA of claim 15, wherein at least a portion of the third VCSEL array is interleaved within the first VCSEL array.

17. The DCA of claim 13, wherein the optical assembly includes a cylindrical lens, and light from the first VCSEL array is refracted by the cylindrical lens to form the bar pattern, and light from the first VCSEL array and the second VCSEL array is refracted by the cylindrical lens to form the flood illumination.

18. The DCA of claim 13, the first VCSEL array includes two adjacent strip sources that are parallel to each other and are separated by gap, and there is a corresponding second VCSEL that has its emission region positioned along a line parallel to the two adjacent strip sources that passes through a center of the gap.

19. The DCA of claim 13, wherein the first VCSEL array is arranged as a plurality of parallel strip sources and each of the plurality of strip sources includes a plurality of first VCSELs, and adjacent emission regions of the plurality second VCSELs are separated by respective gaps, and each of the plurality of strip sources is positioned to bisect a different gap.

20. The DCA of claim 13, further comprising:
a laser driver is configured to provide a drive current to a first strip source of the first VCSEL array and a second strip source of the second VCSEL array, and the drive current provided to the second strip source is a factor of 8 less than the drive current provided to the first strip source.

21. A non-transitory computer readable medium configured to store program code instructions, when executed by a processor of a depth camera assembly (DCA), cause the DCA to perform steps comprising:
instructing a vertical cavity surface emitting laser (VCSEL) chip to emit light in order to form one of flood illumination or a bar pattern, wherein the VCSEL chip comprises:
a first VCSEL array including a plurality of first VCSELs on a substrate,
a second VCSEL array including a plurality of second VCSELs on the substrate, the second VCSEL array positioned orthogonal to the first VCSEL array on the substrate;
conditioning, via an optical assembly, light from the VCSEL chip;
projecting the conditioned light into a local area of the DCA, the conditioned light forming one of the bar pattern or the flood illumination, wherein light emitted from the first VCSEL array is used to form the bar pattern, and wherein light emitted from the first VCSEL array and the second VCSEL array together is used to form the flood illumination;
capturing images of the local area illuminated with the conditioned light; and
determining depth information for the local area using the captured images.
